(19) United States
(12) Patent Application Publication
(10) Pub. No.: US 2026/0202450 A1
(43) Pub. Date: Jul. 16, 2026

(54) POWER DETECTOR

(71) Applicant: Fujikura Ltd., Tokyo (JP)

(72) Inventor: Chihiro Kamidaki, Sakura-shi (JP)

(73) Assignee: Fujikura Ltd., Tokyo (JP)

(21) Appl. No.: 19/438,851

(22) Filed: Jan. 2, 2026

(30) Foreign Application Priority Data
Jan. 10, 2025 (JP) 2025-003914

(51) Int. Cl. G01R 21/14; G01R 19/00; G01R 19/22

(52) U.S. Cl. CPC G01R 21/14; G01R 19/0092; G01R 19/22

(57) ABSTRACT

A power detector includes: a rectifier that generates a detection signal indicating power of a detected signal by rectifying the detected signal based on a predetermined threshold voltage; and a bias adjuster that adjusts a bias voltage of the rectifier to suppress a temperature fluctuation of the detection signal.

### CROSS-REFERENCE TO RELATED APPLICATION

Priority is claimed on Japanese Patent Application No. 2025-003914 filed January 10, 2025, the content of which is incorporated herein by reference.

### BACKGROUND OF THE INVENTION

### Field of the Invention

The present invention relates to a power detector.

### Description of Related Art

In the article titled On-chip Sensing and Actuation Methods for Integrated Self-healing mm-Wave CMOS Power Amplifier (2012 IEEE), a power detector configured of a rectifier that is configured of an n-type MOSFET, a p-type MOS current mirror that is configured of a p-type MOSFET and includes a low-pass filter, a current amplifier that is configured of an n-type MOSFET, a second p-type MOS current mirror that is configured of a p-type MOSFET, and a resistor is disclosed (see FIG. 4 of the above article).

In this power detector, a bias voltage is superimposed on an RF signal and input to a gate of the n-type MOSFET of the rectifier, thereby operating the n-type MOSFET as a half-wave rectifier. That is, the rectifier in the power detector generates a half-wave rectified current that converts only a positive voltage of the RF signal into a current and blocks a negative voltage of the RF signal, and outputs the half-wave rectified current to the p-type MOS current mirror. The p-type MOS current mirror converts the half-wave rectified current into a voltage and passes the voltage through the low-pass filter to convert the voltage into a direct current voltage.

This direct current voltage is a detection signal indicating a magnitude of the RF signal. The detection signal is input from the p-type MOS current mirror to the current amplifier, is amplified in terms of current, and is converted into a detection current. This detection current is folded back by the second p-type MOS current mirror, is converted into the voltage (detection voltage) by the resistor and is output to the outside.

### SUMMARY OF THE INVENTION

As is well known, a threshold voltage of the n-type MOSFET has a property of fluctuating depending on a temperature. In the above background technology, the bias voltage is applied from the outside to the gate of the n-type MOSFET of the rectifier, but when the half-wave rectified current output from the rectifier is converted into a voltage, this voltage is a sum of the bias voltage and the voltage based on the half-wave rectified current, and thus fluctuates with the temperature under the influence of the threshold voltage. Therefore, in the above-described background technology, it is difficult to accurately detect power of the RF signal.

The present invention is made in view of the above circumstances, and an object of the present invention is to provide a power detector capable of more accurately measuring power of a detected signal.

A power detector of a first aspect includes a rectifier that generates a detection signal indicating power of a detected signal by rectifying the detected signal based on a predetermined threshold voltage; and a bias adjuster that adjusts a bias voltage of the rectifier to suppress a temperature fluctuation of the detection signal.

According to the power detector of a second aspect, in the first aspect, the bias adjuster adjusts the bias voltage by adjusting a first current flowing into the rectifier based on the detection signal.

According to the power detector of a third aspect, in the second aspect, the bias adjuster is a current mirror that adjusts the first current by subtracting a second current from a reference current.

According to the power detector of a fourth aspect, in the second or third aspect, the rectifier includes a first current mirror circuit consisting of an input-side circuit and an output-side circuit, the input-side circuit generates the bias voltage by performing current/voltage conversion on the first current, and the output-side circuit generates a rectified current by rectifying the detected signal by the bias voltage.

According to the power detector of a fifth aspect, in the fourth aspect, the rectifier includes a second current mirror circuit and a third current mirror circuit that individually generate a detection current based on the rectified current, the second current mirror circuit outputs the detection current as the detection signal to the bias adjuster, and the third current mirror circuit outputs the detection current to a current/voltage converter.

According to the power detector of a sixth aspect, in the fifth aspect, the second current mirror circuit and the third current mirror circuit include a smoothing circuit that smoothes the rectified current.

According to an aspect of the present invention, it is possible to provide a power detector capable of more accurately measuring power of a detected signal.

### BRIEF DESCRIPTION OF THE DRAWINGS

FIG. 1 is a circuit diagram showing a configuration of a power detector according to an embodiment of the present invention.

FIG. 2 is a block diagram showing a basic configuration of the power detector according to an embodiment of the present invention.

FIG. 3 is a waveform diagram showing a rectification operation in the power detector according to an embodiment of the present invention.

FIG. 4 is a characteristic diagram showing a performance of the power detector according to an embodiment of the present invention.

### DETAILED DESCRIPTION OF THE INVENTION

Hereinafter, an embodiment of the present invention will be described with reference to the drawings.

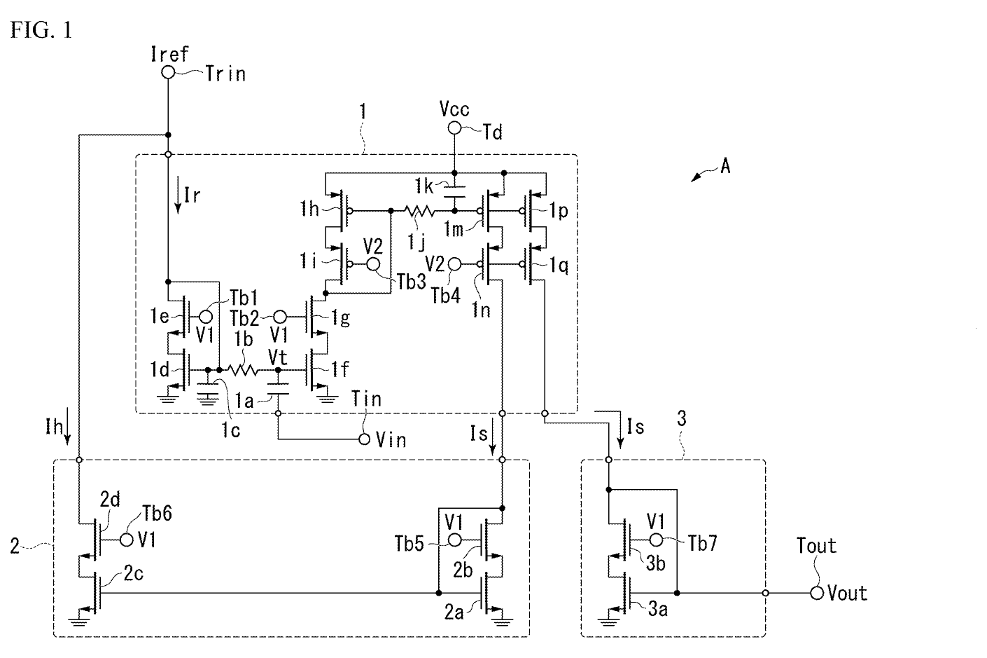

As shown in FIG. 1, a power detector A according to the present embodiment includes an input terminal Tin, a bias current input terminal Trin, a power supply terminal Td, a rectifier 1, a current mirror 2, a current/voltage converter 3, and an output terminal Tout.

The rectifier 1 includes a first bias terminal Tb1, a second bias terminal Tb2, a third bias terminal Tb3, a fourth bias terminal Tb4, a first capacitor 1a, a first resistor 1b, a second capacitor 1c, a first transistor 1d, a second transistor 1e, a third transistor 1f, a fourth transistor 1g, a fifth transistor 1h, a sixth transistor 1i, a second resistor 1j, a third capacitor 1k, a seventh transistor 1m, an eighth transistor 1n, a ninth transistor 1p, and a tenth transistor 1q.

The current mirror 2 includes a fifth bias terminal Tb5, a sixth bias terminal Tb6, an eleventh transistor 2a, a twelfth transistor 2b, a thirteenth transistor 2c, and a fourteenth transistor 2d. The current/voltage converter 3 includes a seventh bias terminal Tb7, a fifteenth transistor 3a, and a sixteenth transistor 3b.

The input terminal Tin is connected to a first end of the first capacitor 1a as shown in the drawing. Although not shown, the input terminal Tin is connected to a high-frequency signal source outside the power detector A. A high-frequency signal having a predetermined frequency, for example, in a range of several to several tens of GHz is input as an input signal Vin to the input terminal Tin from the high-frequency signal source.

The bias current input terminal Trin is connected to a gate terminal of the first transistor 1d, a second end of the first resistor 1b, a first end of the second capacitor 1c, a drain terminal of the second transistor 1e, and a first input end of the current mirror 2. The bias current input terminal Trin is connected to an output terminal of a reference current source outside the power detector A.

A predetermined reference current Iref is input to such a bias current input terminal Trin from the reference current source. The reference current Iref is split into the rectifier 1 and the current mirror 2 as shown in the drawing. That is, a first current Ir flows into the rectifier 1, and a second current Ih flows into the current mirror 2.

The power supply terminal Td is connected to a source terminal of the fifth transistor 1h, a second end of the third capacitor 1k, a source terminal of the seventh transistor 1m, and a source terminal of the ninth transistor 1p. The power supply terminal Td is connected to an output end of a direct current power supply outside the power detector A. A power supply voltage Vcc is supplied to such a power supply terminal Td from a direct current power supply.

As shown in the drawing, the output terminal Tout is connected to a drain terminal of the tenth transistor 1q, a drain terminal of the sixteenth transistor 3b, and a gate terminal of the fifteenth transistor 3a. The output terminal Tout is connected to an input end of a rear stage circuit outside the power detector A. Such an output terminal Tout outputs an output signal Vout of the power detector A to the rear stage circuit.

In the rectifier 1, the first bias terminal Tb1 is connected to a gate terminal of the second transistor 1e. In addition, the first bias terminal Tb1 is connected to a first output end of an external bias circuit outside the power detector A. A first bias voltage V1 is supplied to such a first bias terminal Tb1 from the external bias circuit.

The second bias terminal Tb2 is connected to a gate terminal of the fourth transistor 1g. In addition, the second bias terminal Tb2 is connected to the first output end of the external bias circuit, similar to the first bias terminal Tb1 outside the power detector A. The first bias voltage V1 is supplied to such a second bias terminal Tb2 from the external bias circuit.

The third bias terminal Tb3 is connected to a gate terminal of the sixth transistor 1i. In addition, the third bias terminal Tb3 is connected to a second output end of the external bias circuit outside the power detector A. A second bias voltage V2 is supplied to such a third bias terminal Tb3 from the external bias circuit.

The fourth bias terminal Tb4 is connected to a gate terminal of the eighth transistor 1n and a gate terminal of the tenth transistor 1q. In addition, the fourth bias terminal Tb4 is connected to the second output end of the external bias circuit, similar to the third bias terminal Tb3 outside the power detector A. The second bias voltage V2 is supplied to such a fourth bias terminal Tb4 from the external bias circuit.

The first end of the first capacitor 1a is connected to the input terminal Tin, and a second end of the first capacitor 1a is connected to a first end of the first resistor 1b and the gate terminal of the third transistor 1f. The first capacitor 1a is a coupling capacitor having a predetermined capacitance (first capacitance). That is, the first capacitor 1a causes only an alternating current component of the input signal Vin to input to a first end of the first resistor 1b and the gate terminal of the third transistor 1f.

The first end of the first resistor 1b is connected to a second end of the first capacitor 1a and the gate terminal of the third transistor 1f, and the second end of the first resistor 1b is connected to the first end of the second capacitor 1c, the gate terminal of the first transistor 1d, the drain terminal of the second transistor 1e, and the bias current input terminal Trin. The first resistor 1b has a predetermined resistance value (first resistance value) and constitutes a low-pass filter together with the second capacitor 1c.

In this low-pass filter, a cut-off frequency is determined by the first resistance value and a capacitance (second capacitance) of the second capacitor 1c. The cut-off frequency is set to a frequency sufficiently lower than a frequency of the input signal Vin (high-frequency signal).

Such a first resistor 1b prevents the input signal Vin from being input to the gate terminal of the first transistor 1d together with the second capacitor 1c.

The first end of the second capacitor 1c is connected to the second end of the first resistor 1b, the gate terminal of the third transistor 1f, the drain terminal of the second transistor 1e, and the bias current input terminal Trin, and a second end of the second capacitor 1c is grounded as shown in the drawing. The second capacitor 1c has a predetermined capacitance (second capacitance) and constitutes a low-pass filter together with the first resistor 1b. Such a second capacitor 1c constitutes the low-pass filter described above together with the first resistor 1b, and prevents the input signal Vin from being input to the gate terminal of the first transistor 1d.

The first transistor 1d is an n-type metal oxide semiconductor (MOS) transistor as shown in the drawing. The gate terminal of the first transistor 1d is connected to the second end of the first resistor 1b, the first end of the second capacitor 1c, the drain terminal of the second transistor 1e, and the bias current input terminal Trin, and the source terminal of the first transistor 1d is grounded as shown in the drawing.

In addition, a drain terminal of the first transistor 1d is connected to a source terminal of the second transistor 1e. Such a first transistor 1d includes a structure in which the gate terminal and the drain terminal are connected to each other via the second transistor 1e, that is, a structure in which the gate terminal and the drain terminal are diode-connected via the second transistor 1e.

The second transistor 1e is an n-type MOS transistor, similar to the first transistor 1d. The gate terminal of the second transistor 1e is connected to the first bias terminal Tb1, and the source terminal of the second transistor 1e is connected to the drain terminal of the first transistor 1d. In addition, the drain terminal of the second transistor 1e is connected to the second end of the first resistor 1b, the first end of the second capacitor 1c, the gate terminal of the first transistor 1d, and the bias current input terminal Trin.

The second transistor 1e is the n-type MOS transistor, similar to the first transistor 1d. In addition, the second transistor 1e is a cascode transistor that is cascode-connected to the first transistor 1d. Further, the second transistor 1e constitutes a signal conversion circuit that converts the first current Ir into a direct current voltage together with the first transistor 1d.

That is, the second transistor 1e functions as a gate bias circuit that generates a gate bias voltage together with the first transistor 1d. The gate bias voltage is a gate voltage (direct current voltage) of the third transistor 1f based on the first current Ir input to the bias current input terminal Trin from the outside, and is a bias voltage in a half-wave rectification operation of the third transistor 1f.

Here, the first resistor 1b, the second capacitor 1c, the first transistor 1d, and the second transistor 1e described above are a gate bias generation circuit that generates the gate bias voltage based on the first current Ir. Such a gate bias generation circuit functions as a bias adjuster that adjusts the gate voltage of the third transistor 1f (rectifying transistor).

That is, the bias adjuster consisting of the first resistor 1b, the second capacitor 1c, the first transistor 1d, and the second transistor 1e sets the bias voltage in the half-wave rectification operation of the third transistor 1f (rectifying transistor) by outputting the gate bias voltage generated based on the first current Ir to the gate terminal of the third transistor 1f (rectifying transistor).

The third transistor 1f is the n-type MOS transistor as shown in the drawing. The gate terminal of the third transistor 1f is connected to the second end of the first capacitor 1a and the first end of the first resistor 1b, and the source terminal of the third transistor 1f is grounded as shown in the drawing. In addition, the drain terminal of the third transistor 1f is connected to the source terminal of the fourth transistor 1g.

Such a third transistor 1f performs half-wave rectification processing on the input signal Vin (high-frequency signal) which is a detected signal. That is, the third transistor 1f uses the gate bias voltage supplied from the bias adjuster in the present embodiment as the bias voltage in the half-wave rectification, and performs the half-wave rectification processing on the input signal Vin (high-frequency signal).

The third transistor 1f outputs a half-wave rectified current generated by the half-wave rectification processing of the input signal Vin (high-frequency signal) from the drain terminal to the source terminal of the fourth transistor 1g. Such a third transistor 1f is a rectifying transistor that performs the half-wave rectification processing on the input signal Vin (high-frequency signal).

The third transistor 1f (rectifying transistor) has a threshold voltage Vt unique to the MOS transistor element which is a semiconductor element. The threshold voltage Vt has a property of fluctuating depending on the temperature.

The fourth transistor 1g is the n-type MOS transistor, similar to the third transistor 1f. The gate terminal of the fourth transistor 1g is connected to the second bias terminal Tb2, and the source terminal of the fourth transistor 1g is connected to the drain terminal of the third transistor 1f.

In addition, the drain terminal of the fourth transistor 1g is connected to the gate terminal of the fifth transistor 1h, the drain terminal of the sixth transistor 1i, and a first end of the second resistor 1j. Such a fourth transistor 1g is the cascode transistor that is cascode-connected to the third transistor 1f.

Here, the first transistor 1d and the second transistor 1e that are diode-connected, the first resistor 1b and the second capacitor 1c that constitute the low-pass filter, and the third transistor 1f and the fourth transistor 1g that are cascode-connected constitute a first current mirror circuit as a whole.

The first transistor 1d, the second transistor 1e, the first resistor 1b, and the second capacitor 1c constitute an input-side circuit in the first current mirror circuit. In addition, the third transistor 1f and the fourth transistor 1g constitute an output-side circuit in the first current mirror circuit.

In such a first current mirror circuit, the first transistor 1d and the second transistor 1e constituting the input-side circuit, and the third transistor 1f and the fourth transistor 1g constituting the output-side circuit are configured to have the same element size. Therefore, the first current mirror circuit is a current mirror circuit having a mirror ratio of "1".

That is, in a reference state where the input signal Vin (high-frequency signal) is not input to the input terminal Tin, the first current Ir flows in the output-side circuit of the first current mirror circuit. In addition, in the operation state where the input signal Vin (high-frequency signal) is input to the input terminal Tin, the third transistor 1f half-wave rectifies the input signal Vin (high-frequency signal). Therefore, a superimposed current in which a half-wave rectified current indicating the power of the input signal Vin (high-frequency signal) is superimposed on the first current Ir flows in the output-side circuit of the first current mirror circuit.

Here, in a case where the temperature fluctuation of the threshold voltage Vt occurs in the third transistor 1f (rectifying transistor) in the reference state, a composite superimposed current in which a current drift component caused by the temperature fluctuation of the threshold voltage Vt is superimposed on the first current Ir flows in the output-side circuit of the first current mirror circuit.

On the other hand, in a case where the temperature fluctuation of the threshold voltage Vt occurs in the third transistor 1f (rectifying transistor) in the operation state, the composite superimposed current in which the current drift component caused by the temperature fluctuation of the threshold voltage Vt is superimposed on the first current Ir and the half-wave rectified current flows in the output-side circuit of the first current mirror circuit.

The fifth transistor 1h is a p-type MOS transistor as shown in the drawing. The gate terminal of the fifth transistor 1h is connected to the drain terminal of the fourth transistor 1g, the drain terminal of the sixth transistor 1i, and the first end of the second resistor 1j, and the drain terminal of the fifth transistor 1h is connected to the source terminal of the sixth transistor 1i.

In addition, the source terminal of the fifth transistor 1h is connected to the power supply terminal Td, the second end of the third capacitor 1k, the source terminal of the seventh transistor 1m, and the source terminal of the ninth transistor 1p. That is, such a fifth transistor 1h is connected in series with the third transistor 1f and the fourth transistor 1g via the sixth transistor 1i, and a drain current equal to the first current Ir flows in the reference state.

Furthermore, the fifth transistor 1h has a structure in which the gate terminal and the drain terminal are connected to each other via the sixth transistor 1i. That is, the fifth transistor 1h has a structure in which the gate terminal and the drain terminal are diode-connected via the sixth transistor 1i.

The sixth transistor 1i is the p-type MOS transistor, similar to the fifth transistor 1h. The gate terminal of the sixth transistor 1i is connected to the third bias terminal Tb3, and the source terminal of the sixth transistor 1i is connected to the drain terminal of the fifth transistor 1h. In addition, the drain terminal of the sixth transistor 1i is connected to the drain terminal of the fourth transistor 1g, the gate terminal of the fifth transistor 1h, and the first end of the second resistor 1j.

Such a sixth transistor 1i is the cascode transistor that is cascode-connected to the fifth transistor 1h. In addition, the sixth transistor 1i is connected in series with the third transistor 1f and the fourth transistor 1g together with the fifth transistor 1h, and the drain current equal to the first current Ir flows in the reference state.

The first end of the second resistor 1j is connected to the drain terminal of the fourth transistor 1g, the gate terminal of the fifth transistor 1h, and the drain terminal of the sixth transistor 1i, and a second end of the second resistor 1j is connected to a first end of the third capacitor 1k, the gate terminal of the seventh transistor 1m, and the gate terminal of the ninth transistor 1p. The second resistor 1j has a predetermined resistance value (second resistance value) and constitutes a smoothing circuit together with the third capacitor 1k.

In the smoothing circuit, a time constant is determined by the second resistance value and the capacitance of the third capacitor 1k (third capacitance). This time constant is set such that the half-wave rectified current included in the superimposed current input from the drain terminal of the fourth transistor 1g can be sufficiently smoothed. Such a second resistor 1j applies the detection voltage Vs in which the superimposed current is smoothed to the gate terminal of the seventh transistor 1m and the gate terminal of the ninth transistor 1p.

This detection voltage Vs is a direct current voltage that is obtained by smoothing the superimposed current input from the drain terminal of the fourth transistor 1g and that indicates the power of the input signal Vin (high-frequency signal). In addition, the detection voltage Vs sets the gate voltage of the seventh transistor 1m and the gate voltage of the ninth transistor 1p.

The first end of the third capacitor 1k is connected to the second end of the second resistor 1j, the gate terminal of the seventh transistor 1m, and the gate terminal of the ninth transistor 1p, and the second end of the third capacitor 1k is connected to the power supply terminal Td, the source terminal of the fifth transistor 1h, the source terminal of the seventh transistor 1m, and the source terminal of the ninth transistor 1p.

The third capacitor 1k has a predetermined capacitance (third capacitance) and constitutes the smoothing circuit together with the second resistor 1j. That is, the third capacitor 1k generates the detection voltage Vs in which the superimposed current is smoothed together with the second resistor 1j to apply the detection voltage Vs to the gate terminal of the seventh transistor 1m and the gate terminal of the ninth transistor 1p.

The seventh transistor 1m is the p-type MOS transistor as shown in the drawing. The gate terminal of the seventh transistor 1m is connected to the second end of the second resistor 1j, the first end of the third capacitor 1k, and the gate terminal of the ninth transistor 1p, and the drain terminal of the seventh transistor 1m is connected to the source terminal of the eighth transistor 1n.

In addition, the source terminal of the seventh transistor 1m is connected to the power supply terminal Td, the source terminal of the fifth transistor 1h, the second end of the third capacitor 1k, and the source terminal of the ninth transistor 1p. That is, the seventh transistor 1m is cascode-connected to the eighth transistor 1n and is electrically connected to the second input end of the current mirror 2 via the eighth transistor 1n.

The eighth transistor 1n is the p-type MOS transistor, similar to the seventh transistor 1m. The gate terminal of the eighth transistor 1n is connected to the fourth bias terminal Tb4 and the gate terminal of the tenth transistor 1q, and the source terminal of the eighth transistor 1n is connected to the drain terminal of the seventh transistor 1m.

In addition, the drain terminal of the eighth transistor 1n is connected to the second input end of the current mirror 2. Such an eighth transistor 1n is the cascode transistor that is cascode-connected to the seventh transistor 1m.

Here, the fifth transistor 1h and the sixth transistor 1i that are diode-connected, the second resistor 1j and the third capacitor 1k that constitute the smoothing circuit, and the seventh transistor 1m and the eighth transistor 1n that are cascode-connected constitute the second current mirror circuit as a whole.

In the second current mirror circuit, the fifth transistor 1h and the sixth transistor 1i constituting the input-side circuit, and the seventh transistor 1m and the eighth transistor 1n constituting the output-side circuit are configured to have the same element size. Therefore, the second current mirror circuit is the current mirror circuit having the mirror ratio of "1".

In such a second current mirror circuit, in the operation state where the input signal Vin (high-frequency signal) is input to the input terminal Tin, the drain currents (direct currents) of the seventh transistor 1m and the eighth transistor 1n constituting the output-side circuit are equal to the drain currents, that is, the superimposed currents of the fifth transistor 1h and the sixth transistor 1i constituting the input-side circuit.

In this operation state, the detection current Is is output from the output-side circuit of the second current mirror circuit to the current mirror 2 based on the detection voltage Vs generated from the superimposed current in the smoothing circuit of the second current mirror circuit. That is, the second current mirror circuit generates the detection current Is for outputting to the current mirror 2 based on the half-wave rectified current input from the first current mirror circuit.

The detection current Is generated by the second current mirror circuit is the detection signal indicating the power of the input signal Vin (high-frequency signal) that is the detected signal. In addition, although details will be described later, the detection current Is is obtained by removing or suppressing the influence of the current drift component due to the temperature fluctuation of the threshold voltage Vt of the third transistor 1f (rectifying transistor).

The ninth transistor 1p is the p-type MOS transistor as shown in the drawing. The gate terminal of the ninth transistor 1p is connected to the second end of the second resistor 1j, the first end of the third capacitor 1k, and the gate terminal of the seventh transistor 1m, and the drain terminal of the ninth transistor 1p is connected to the source terminal of the tenth transistor 1q.

In addition, the source terminal of the ninth transistor 1p is connected to the power supply terminal Td, the source terminal of the fifth transistor 1h, the second end of the third capacitor 1k, and the source terminal of the seventh transistor 1m. That is, the ninth transistor 1p is cascode-connected to the tenth transistor 1q and is electrically connected to the input end of the current/voltage converter 3 via the tenth transistor 1q.

The tenth transistor 1q is the p-type MOS transistor, similar to the ninth transistor 1p. The gate terminal of the tenth transistor 1q is connected to the fourth bias terminal Tb4 and the gate terminal of the eighth transistor 1n, and the source terminal of the tenth transistor 1q is connected to the drain terminal of the ninth transistor 1p.

In addition, the drain terminal of the tenth transistor 1q is connected to the input end of the current/voltage converter 3. Such a tenth transistor 1q is the cascode transistor that is cascode-connected to the ninth transistor 1p.

Here, the fifth transistor 1h and the sixth transistor 1i that are diode-connected, the second resistor 1j and the third capacitor 1k that constitute the smoothing circuit, and the ninth transistor 1p and the tenth transistor 1q that are cascode-connected constitute the third current mirror circuit as a whole.

In the third current mirror circuit, the fifth transistor 1h and the sixth transistor 1i constituting the input-side circuit, and the ninth transistor 1p and the tenth transistor 1q constituting the output-side circuit are configured to have the same element size. Therefore, the third current mirror circuit is a current mirror circuit in which the mirror ratio is "1", similar to the second current mirror circuit.

In such a third current mirror circuit, in the operation state where the input signal Vin (high-frequency signal) is input to the input terminal Tin, the drain currents (direct currents) of the ninth transistor 1p and the tenth transistor 1q constituting the output-side circuit are equal to the drain currents, that is, the superimposed currents of the fifth transistor 1h and the sixth transistor 1i constituting the input-side circuit.

In this operation state, the detection current Is is output from the output-side circuit of the third current mirror circuit to the current/voltage converter 3 based on the detection voltage Vs generated from the superimposed current in the smoothing circuit of the third current mirror circuit. That is, the third current mirror circuit generates the detection current Is for output to the outside based on the half-wave rectified current input from the first current mirror circuit.

The detection current Is generated by the third current mirror circuit is the detection signal indicating the power of the input signal Vin (high-frequency signal). In addition, although details will be described later, the detection current Is is obtained by removing or suppressing the influence of the current drift component due to the temperature fluctuation of the threshold voltage Vt of the third transistor 1f (rectifying transistor).

In the current mirror 2, the fifth bias terminal Tb5 is connected to the gate terminal of the twelfth transistor 2b. In addition, the fifth bias terminal Tb5 is connected to the first output end of the external bias circuit outside the power detector A, similar to the first bias terminal Tb1 and the second bias terminal Tb2 of the rectifier 1. The first bias voltage V1 is supplied to such a fifth bias terminal Tb5 from the external bias circuit.

The sixth bias terminal Tb6 is connected to the gate terminal of the fourteenth transistor 2d.

In addition, the sixth bias terminal Tb6 is connected to the first output end of the external bias circuit outside the power detector A, similar to the fifth bias terminal Tb5. The first bias voltage V1 is supplied to such a sixth bias terminal Tb6 from the external bias circuit.

The eleventh transistor 2a is the n-type MOS transistor as shown in the drawing. The gate terminal of the eleventh transistor 2a is connected to the drain terminal of the twelfth transistor 2b and the gate terminal of the thirteenth transistor 2c, and the source terminal of the eleventh transistor 2a is grounded as shown in the drawing.

In addition, the drain terminal of the eleventh transistor 2a is connected to the source terminal of the twelfth transistor 2b. Such an eleventh transistor 2a has a structure in which the gate terminal and the drain terminal are connected to each other via the twelfth transistor 2b, that is, a structure in which the gate terminal and the drain terminal are diode-connected via the twelfth transistor 2b.

The twelfth transistor 2b is the n-type MOS transistor, similar to the eleventh transistor 2a. The gate terminal of the twelfth transistor 2b is connected to the fifth bias terminal Tb5, and the source terminal of the twelfth transistor 2b is connected to the drain terminal of the eleventh transistor 2a. That is, the twelfth transistor 2b is the cascode transistor that is cascode-connected to the eleventh transistor 2a.

The drain terminal of the twelfth transistor 2b is connected to the gate terminal of the eleventh transistor 2a, the gate terminal of the thirteenth transistor 2c, and the drain terminal of the eighth transistor 1n in the rectifier 1, that is, the output end of the second current mirror circuit in the rectifier 1. That is, the drain terminal of the twelfth transistor 2b is the second input end of the current mirror 2.

In the operation state where the input signal Vin (high-frequency signal) is input to the input terminal Tin, the superimposed current in which the half-wave rectified current indicating the power of the input signal Vin (high-frequency signal) is superimposed on the first current Ir flows in the drain terminal (second input end of the current mirror 2) of such a twelfth transistor 2b from the second current mirror circuit of the rectifier 1.

In addition, in a case where the temperature fluctuation of the threshold voltage Vt of the third transistor 1f (rectifying transistor) occurs in this operation state, the detection current Is flows from the second current mirror circuit of the rectifier 1 based on the composite superimposed current in which the current drift component caused by the temperature fluctuation of the threshold voltage Vt is superimposed on the first current Ir and the half-wave rectified current.

The thirteenth transistor 2c is the n-type MOS transistor, similar to the eleventh transistor 2a. The gate terminal of the thirteenth transistor 2c is connected to the gate terminal of the eleventh transistor 2a, the drain terminal of the twelfth transistor 2b, and the drain terminal of the eighth transistor 1n in the rectifier 1. In addition, the source terminal of the thirteenth transistor 2c is grounded as shown in the drawing, and the drain terminal of the thirteenth transistor 2c is connected to the source terminal of the fourteenth transistor 2d.

The fourteenth transistor 2d is the n-type MOS transistor, similar to the thirteenth transistor 2c which is described above. The gate terminal of the fourteenth transistor 2d is connected to the sixth bias terminal Tb6, and the source terminal of the fourteenth transistor 2d is connected to the drain terminal of the thirteenth transistor 2c. Such a fourteenth transistor 2d is the cascode transistor that is cascode-connected to the thirteenth transistor 2c.

The drain terminal of such a fourteenth transistor 2d is the first input end of the current mirror 2, and the second current Ih flows into the drain terminal via the bias current input terminal Trin. The second current Ih is equal to the detection current Is flowing into the second input end of the current mirror 2 according to the circuit characteristics of a well-known current mirror circuit.

That is, in the reference state where the input signal Vin (high-frequency signal) is not input to the input terminal Tin, and in the reference temperature state where the operating temperature of the third transistor 1f functioning as the rectifying transistor does not fluctuate, the second current Ih flowing into the first input end of the current mirror 2 is equal to the detection current Is flowing into the second input end of the current mirror 2.

Such a current mirror 2 is the bias adjuster in the present embodiment. That is, the current mirror 2 adjusts the first current Ir based on the rectifying signal (detection current Is) in the present embodiment to adjust the gate bias voltage of the third transistor 1f (rectifying transistor) such that the temperature fluctuation of the detection current Is is suppressed.

More specifically, the current mirror 2 adjusts the first current Ir by subtracting the second current Ih from the reference current Iref based on the rectifying signal (detection current Is). That is, the current mirror 2 adjusts the first current Ir by adjusting the subtraction amount from the reference current Iref, and thus adjusts the gate bias voltage.

In the current/voltage converter 3, the seventh bias terminal Tb7 is connected to the gate terminal of the sixteenth transistor 3b. In addition, the seventh bias terminal Tb7 is connected to the first output end of the external bias circuit outside the power detector A, similar to the first bias terminal Tb1 and the second bias terminal Tb2 in the rectifier 1 and the fifth bias terminal Tb5 and the sixth bias terminal Tb6 in the current mirror 2. The first bias voltage V1 is supplied to such a seventh bias terminal Tb7 from the external bias circuit as shown in the drawing.

The fifteenth transistor 3a is the n-type MOS transistor as shown in the drawing. The gate terminal of the fifteenth transistor 3a is connected to the output terminal Tout, and the drain terminal of the sixteenth transistor 3b, and the drain terminal of the tenth transistor 1q in the rectifier 1, that is, the output end of the third current mirror circuit in the rectifier 1.

In addition, the drain terminal of the fifteenth transistor 3a is connected to the source terminal of the sixteenth transistor 3b, and the source terminal of the fifteenth transistor 3a is grounded as shown in the drawing. Such a fifteenth transistor 3a has a structure in which the gate terminal and the drain terminal are connected to each other via the sixteenth transistor 3b, that is, a structure in which the gate terminal and the drain terminal are diode-connected via the sixteenth transistor 3b.

The sixteenth transistor 3b is the n-type MOS transistor, similar to the fifteenth transistor 3a. The gate terminal of the sixteenth transistor 3b is connected to the seventh bias terminal Tb7, and the source terminal of the sixteenth transistor 3b is connected to the drain terminal of the fifteenth transistor 3a. That is, the sixteenth transistor 3b is the cascode transistor that is cascode-connected to the fifteenth transistor 3a.

The drain terminal of the sixteenth transistor 3b is connected to the output terminal Tout, the gate terminal of the fifteenth transistor 3a, and the drain terminal of the tenth transistor 1q in the rectifier 1, that is, the output end of the third current mirror circuit in the rectifier 1. The drain terminal of such a sixteenth transistor 3b is the input end of the current/voltage converter 3.

The detection current Is flows into the input end of the current/voltage converter 3 from the third current mirror circuit of the rectifier 1. That is, the detection current Is equivalent to the second input end of the current mirror 2 flows into the current/voltage converter 3. The current/voltage converter 3 converts such a detection current Is into the voltage signal and outputs the voltage signal to the output terminal Tout as the output signal Vout.

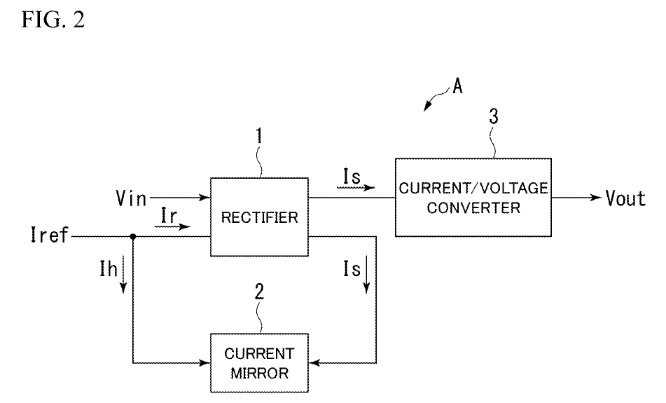

Such a power detector A has a basic configuration shown in FIG. 2. That is, the power detector A splits the reference current Iref supplied from the outside into the first current Ir and the second current Ih, supplies the first current Ir to the rectifier 1, and supplies the second current Ih to the first input end of the current mirror 2. The rectifier 1 generates the detection current Is by the first current Ir and the input signal Vin (high-frequency signal) and supplies the detection current Is to the second input end of the current mirror 2. In addition, the rectifier 1 supplies the detection current Is to the current/voltage converter 3.

The current mirror 2 adjusts the second current Ih flowing into the first input end so as to correct the influence of the temperature fluctuation of the threshold voltage Vt of the third transistor 1f (rectifying transistor) based on the detection current Is input to the second input end. In addition, the current/voltage converter 3 converts the detection current Is into a voltage and outputs the converted voltage to the outside as the output signal Vout.

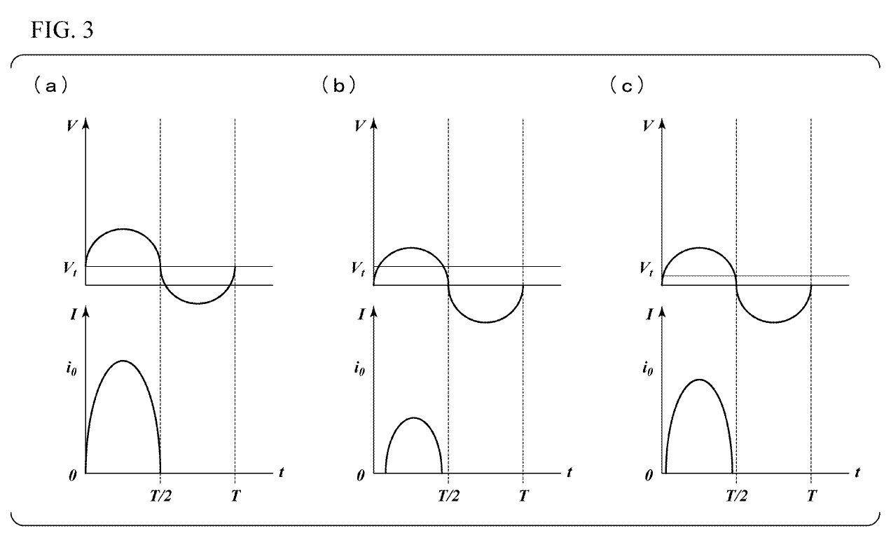

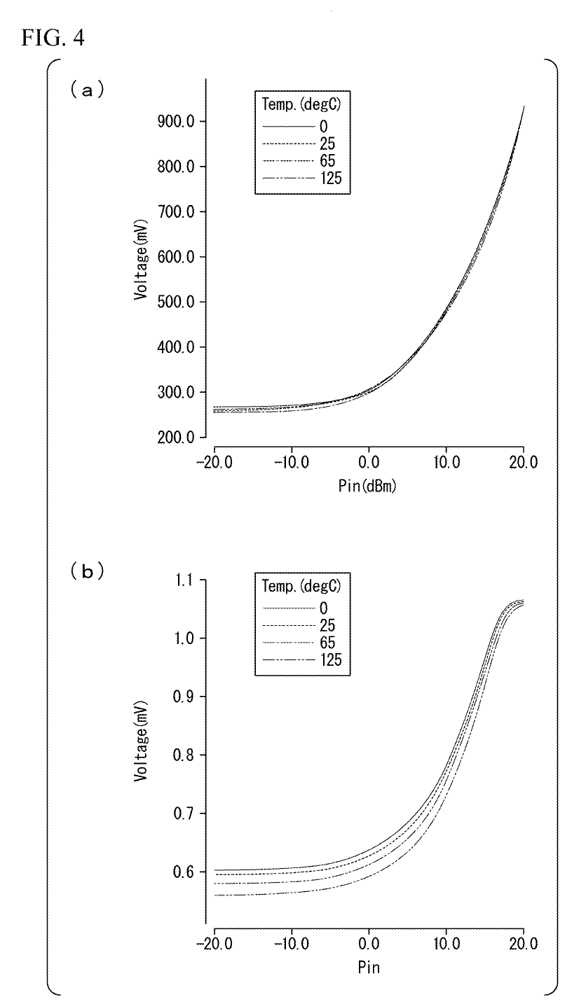

Next, the operation of the power detector A according to the present embodiment will be described in detail with reference to FIGS. 3 and 4.

The rectifier 1 of the power detector A operates based on the reference current Iref input from the reference current source to the bias current input terminal Trin in the operation state where the input signal Vin (high-frequency signal) is input to the input terminal Tin.

That is, in this operation state, as shown in FIG. 3, the third transistor 1f (rectifying transistor) of the rectifier 1 performs half-wave rectification processing on the input signal Vin (high-frequency signal) with the gate bias voltage as an operation point. As a result, in the drain terminal of the third transistor 1f (rectifying transistor), that is, in the output-side circuit of the first current mirror circuit, the superimposed current in which the half-wave rectified current indicating the power of the input signal Vin (high-frequency signal) is superimposed on the first current Ir flows.

Here, part (a) of FIG. 3 shows the half-wave rectified current in a case where the input signal Vin (high-frequency signal) is subjected to the half-wave rectification processing with the gate bias voltage equal to the threshold voltage Vt of the n-type MOS transistor. In addition, part (b) of FIG. 3 shows the half-wave rectified current in a case where the input signal Vin having the same amplitude as that of part (a) of FIG. 3 is subjected to the half-wave rectification processing with the gate bias voltage lower than the threshold voltage Vt of the n-type MOS transistor. Further, part (c) of FIG. 3 shows the half-wave rectified current in a case where the input signal Vin having the same amplitude as that in part (a) of FIG. 3 is subjected to the half-wave rectification processing with the same gate bias voltage as that in part (b) of FIG. 3 in a case where the threshold voltage Vt of the n-type MOS transistor is lower than that in part (b) of FIG. 3, for example, due to the temperature fluctuation or the like.

The superimposed current is converted into the detection voltage Vs by the smoothing circuit of the second current mirror circuit and the third current mirror circuit, and is output as the detection current Is from the output-side circuits of the second current mirror circuit and the third current mirror circuit to the second input end of the current mirror 2 and the input end of the current/voltage converter 3.

Here, when a fluctuation in the operating temperature occurs in the third transistor 1f (rectifying transistor), in the third transistor 1f (rectifying transistor), the threshold voltage Vt increases in response to an increase in the operating temperature and decreases in response to a decrease in the operating temperature. As a result, the current drift component caused by the fluctuation of the threshold voltage Vt is superimposed on the detection current Is.

In the current mirror 2, when the detection current Is input to the second input end fluctuates due to the current drift component, the second current Ih input to the first input end fluctuates in the same manner. The fluctuation of the second current Ih causes the first current Ir flowing into the rectifier 1 to fluctuate. For example, when the detection current Is increases, the second current Ih also increases, and as a result, the first current Ir decreases by an amount of increase in the second current Ih. On the contrary, when the detection current Is decreases, the second current Ih also decreases, and as a result, the first current Ir increases by an amount of decrease of the second current Ih.

That is, the current mirror 2 operates to feedback-correct the gate bias voltage of the third transistor 1f (rectifying transistor) set by the input-side circuit of the first current mirror circuit. Therefore, the influence of the temperature fluctuation of the threshold voltage Vt of the third transistor 1f (rectifying transistor) in the detection current Is is removed or suppressed.

According to the power detector A of the present embodiment, as shown in FIG. 4, it is possible to obtain the output signal Vout (voltage) that is sufficiently stable with respect to the temperature fluctuation of the third transistor 1f (rectifying transistor). That is, as can be seen from the comparison between part (a) of FIG. 4 showing the input and output characteristics of the power detector A according to the present embodiment and part (b) of FIG. 4 showing a comparative example in which the current mirror 2 is not provided, the input and output characteristics of the power detector A according to the present embodiment are sufficiently stable with respect to the temperature fluctuation of the third transistor 1f (rectifying transistor) over 0°C to 125°C.

The power detector A according to the present embodiment includes the rectifier 1 that generates the detection current Is (detection signal) indicating the power of the input signal Vin (detected signal) by half-wave rectifying the input signal Vin (detected signal) based on a predetermined gate bias voltage, and the current mirror 2 (bias adjuster) that adjusts the gate bias voltage to suppress the temperature fluctuation of the detection current Is (detection signal).

According to the present embodiment, the gate bias voltage of the rectifier 1 is adjusted by the current mirror 2 (bias adjuster) to suppress the temperature fluctuation of the detection current Is (detection signal). Therefore, according to the present embodiment, it is possible to provide the power detector A capable of more accurately measuring the power of the input signal Vin (detected signal).

In addition, in the power detector A according to the present embodiment, the current mirror 2 (bias adjuster) adjusts the gate bias voltage by adjusting the first current Ir flowing into the rectifier 1 based on the detection current Is (detection signal). According to the present embodiment, by adjusting the first current Ir, it is possible to easily suppress the temperature fluctuation of the detection current Is (detection signal).

In addition, in the power detector A according to the present embodiment, the bias adjuster is the current mirror 2 that adjusts the first current Ir by subtracting the second current Ih from the reference current Iref. According to the present embodiment, the first current Ir can be easily adjusted by using the current mirror 2, and thus the temperature fluctuation of the detection current Is (detection signal) can be easily suppressed.

In addition, in the power detector A according to the present embodiment, the rectifier 1 includes the first current mirror circuit consisting of the input-side circuit and the output-side circuit, the input-side circuit generates the gate bias voltage by performing the current/voltage conversion on the first current Ir, and the output-side circuit rectifies the input signal Vin (detected signal) by the gate bias voltage.

According to the present embodiment, the gate bias voltage can be easily generated based on the first current Ir by using the first current mirror circuit, and thus the temperature fluctuation of the detection current Is (detection signal) can be easily suppressed.

In addition, in the power detector A according to the present embodiment, the rectifier 1 includes the second current mirror circuit and the third current mirror circuit that individually generate the detection current Is based on the half-wave rectified current, the second current mirror circuit outputs the detection current Is to the current mirror 2 (bias adjuster) as the detection signal, and the third current mirror circuit outputs the detection current Is to the current/voltage converter 3.

According to the present embodiment, since the detection current Is for the current mirror 2 and the detection current Is for output are individually generated by the second current mirror circuit and the third current mirror circuit, it is possible to suppress the detection current Is supplied to the current mirror 2 from being affected by the output circuit, that is, the current/voltage converter 3. Therefore, according to the present embodiment, it is possible to accurately suppress the temperature fluctuation of the detection current Is (detection signal).

In addition, in the power detector A according to the present embodiment, the second current mirror circuit and the third current mirror circuit include the smoothing circuit that smoothes the half-wave rectified current. According to the present invention, it is possible to obtain the stable detection current Is (detection signal).

The present invention is not limited to the above embodiments, and for example, the following modification examples are considered.

(1) In the above-described embodiments, the high-frequency signal in the range of several to several tens of GHz is used as the detected signal, but the present invention is not limited thereto. The present invention can be applied to the power detection in a signal having a frequency other than the above-described frequency band.

(2) In the above-described embodiments, the rectifier 1 is configured as shown in FIG. 1, but the present invention is not limited thereto. Various modification examples are considered for the circuit configuration of the rectifier 1 in addition to the circuit configuration of FIG. 1.

(3) In the above-described embodiments, the bias adjuster of the present invention is configured as the current mirror 2, but the present invention is not limited thereto. Various circuit configurations other than the current mirror 2 can be considered as the circuit configuration of the bias adjuster according to the present invention.

(4) In the above-described embodiments, the MOS transistor (unipolar transistor) is employed as the transistor, but the present invention is not limited thereto. A bipolar transistor may be employed instead of the unipolar transistor. In addition, a unipolar transistor having a structure other than the MOS transistor may be employed.

(5) In the above-described embodiments, the mirror ratio of the first to third current mirror circuits is set to "1", but the present invention is not limited to this. That is, the mirror ratios of the first to third current mirror circuits may be appropriately set as necessary for circuit design. For example, the mirror ratio of the first to third current mirror circuits may be set to a value of 1 or more.

What is claimed is:

1. A power detector comprising:
a rectifier that generates a detection signal indicating power of a detected signal by rectifying the detected signal based on a predetermined threshold voltage; and
a bias adjuster that adjusts a bias voltage of the rectifier to suppress a temperature fluctuation of the detection signal.

2. The power detector according to claim 1,
wherein the bias adjuster adjusts the bias voltage by adjusting a first current flowing into the rectifier based on the detection signal.

3. The power detector according to claim 2,
wherein the bias adjuster is a current mirror that adjusts the first current by subtracting a second current from a reference current.

4. The power detector according to claim 2,
wherein the rectifier includes a first current mirror circuit consisting of an input-side circuit and an output-side circuit,
the input-side circuit generates the bias voltage by performing current/voltage conversion on the first current, and
the output-side circuit generates a rectified current by rectifying the detected signal by the bias voltage.

5. The power detector according to claim 4,
wherein the rectifier includes a second current mirror circuit and a third current mirror circuit that individually generate a detection current based on the rectified current,
the second current mirror circuit outputs the detection current as the detection signal to the bias adjuster, and
the third current mirror circuit outputs the detection current to a current/voltage converter.

6. The power detector according to claim 5,
wherein the second current mirror circuit and the third current mirror circuit include a smoothing circuit that smoothes the rectified current.

7. The power detector according to claim 3,
wherein the rectifier includes a first current mirror circuit consisting of an input-side circuit and an output-side circuit,
the input-side circuit generates the bias voltage by performing current/voltage conversion on the first current, and
the output-side circuit generates a rectified current by rectifying the detected signal by the bias voltage.

8. The power detector according to claim 7,
wherein the rectifier includes a second current mirror circuit and a third current mirror circuit that individually generate a detection current based on the rectified current,
the second current mirror circuit outputs the detection current as the detection signal to the bias adjuster, and
the third current mirror circuit outputs the detection current to a current/voltage converter.

9. The power detector according to claim 8,
wherein the second current mirror circuit and the third current mirror circuit include a smoothing circuit that smoothes the rectified current.
